(19) United States
(12) Patent Application Publication
(10) Pub. No.: US 2006/0088964 A1
(43) Pub. Date: Apr. 27, 2006

(54) Method of forming SRAM cell

(75) Inventors: Hyuck-chai Jung, Suwon-si (KR); Hyeong-mo Yang, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/147,574

(22) Filed: Jun. 8, 2005

(30) Foreign Application Priority Data
Oct. 26, 2004 (KR) 04-85799

(51) Int. Cl. H01L 21/8238; H01L 21/425

(52) U.S. Cl. 438/199; 438/514

(57) ABSTRACT

A method of forming an SRAM cell, having two transfer transistors, two driver transistors, and two load devices which are connected with one another in the form of a flip-flop is provided. In particular, after defining an active region and an inactive region on a silicon substrate, a gate electrode conductive pattern of the transistors is formed on the silicon substrate having the active region and the inactive region formed therein along a channel width direction (X-axis direction). Then, after forming a pocket ion implantation region under the conductive pattern, by performing a photolithography process on the conductive pattern along a channel length direction (Y-axis direction), the gate electrodes of the transistors are formed. Even though the gate electrodes are misaligned, impurities for pocket ion implantation are not injected into the gate extension along the channel width direction.

### BACKGROUND OF THE INVENTION

This application claims the priority of Korean Patent Application No. 10-2004-0085799, filed on Oct. 26, 2004, in the Korean Intellectual Property Office, the disclosure of which is incorporated herein in its entirety by reference.

1. Field of the Invention

The present invention relates to a method of forming a memory cell of a semiconductor device, and more particularly, a method of forming an SRAM cell of an SRAM device.

2. Description of the Related Art

Generally, a static random access memory (SRAM) has the characteristics of high operation speed and low power consumption in comparison with a dynamic random access memory (DRAM), because the SRAM does not need refresh operations. Therefore, the SRAM is widely used for a cache memory of a computer or portable electronic products. The unit cell of the SRAM device is composed of a pair of driver transistors, a pair of transfer transistors, and a pair of load devices.

The SRAM cell is classified as a high load resistor cell or a CMOS type cell, according the the type of load device. The high load resistor cell uses a high load resistor of about 1×10⁹Ω or higher as a load device, and uses an NMOS transistor as a driver transistor and a transfer transistor. The CMOS type cell uses a PMOS transistor as a load device and an NMOS transistor as a driver transistor and a transfer transistor.

The SRAM cell must reduce the threshold voltage mismatch between transistors respectively connected to a bit line BL and a bit line bar /BL, that is, threshold voltage difference (Δ Vth), to the minimum in order to improve a static noise margin. Unless the threshold voltage mismatch can be reduced to the minimum, power supply voltage Vcc margin characteristics are reduced due to the decrease of a cell current, and the static noise margin is not improved.

### SUMMARY OF THE INVENTION

The present invention provides a method of forming a static random access memory (SRAM) cell for reducing threshold voltage mismatch between transistors connected to two nodes of a bit line and a bit line bar.

According to an aspect of the present invention, there is provided a method of forming an SRAM cell, having two transfer transistors, two driver transistors, and two load devices which are connected with one another in the form of flip-flop. According to the method, an active region and an inactive region are defined on a silicon substrate. A gate electrode conductive pattern of the transistors is formed on the silicon substrate having the active region and the inactive region formed therein along a channel width direction (X-axis direction). A pocket ion implantation region is formed under the conductive pattern. A a photolithography process is performed on the conductive pattern along a channel length direction (Y-axis direction), thereby forming gate electrodes of the transistors.

The pocket ion implantation region may be formed by injecting impurities by inclined ion implantation into the silicon substrate having the conductive pattern formed thereon along the channel width direction and the channel length direction. The transfer transistor and the driver transistor may be NMOS transistors, and the load device may be a PMOS transistor. P-type impurities may be injected into the silicon substrate having the transfer transistor and the driver transistor formed thereon to form the pocket ion implantation region, and N-type impurities may be injected into the silicon substrate having the load device formed thereon.

According to another aspect of the present invention, there is provided a method of forming an SRAM cell including a first driver transistor and a first load transistor having a first common gate electrode disposed in an X-axis direction, a second transfer transistor having a gate electrode spaced in parallel from the gate electrode of the first load transistor in an X-axis direction, a first transfer transistor having a gate electrode spaced from the first common gate electrode in a Y-axis direction and disposed in a diagonal direction to the gate electrode of the second transfer transistor, and a second driver transistor and a second load transistor having a second common gate electrode spaced from the second transfer transistor in a Y-axis direction and disposed in a diagonal direction to the first common gate electrode.

The method includes defining an active region and an inactive region on a silicon substrate. A gate electrode conductive pattern of the transistors is formed on the silicon substrate having the active region and the inactive region formed therein along a channel width direction (X-axis direction). A pocket ion implantation region is formed under the conductive pattern. A photolithography process is performed on the conductive pattern along a channel length direction (Y-axis direction), thereby forming gate electrodes of the transistors.

The pocket ion implantation region may be formed by injecting impurities by inclined ion implantation into the silicon substrate having the conductive pattern formed thereon along the channel width direction and the channel length direction. The first common gate electrode of the first driver transistor and the second common gate electrode of the second driver transistor may include gate extensions extended on an inactive region separated from an active region, which is extended to the Y-axis direction, to −X and X-axis directions. Impurities may not be injected into the gate extension along the X-axis direction during the formation of the pocket ion implantation region by the conductive pattern. The transfer transistor and the driver transistor can be NMOS transistors, and the load device can be a PMOS transistor. P-type impurities can be injected intl the silicon substrate having the transfer transistor and the driver transistor formed thereon to form the pocket ion implantation region, and N-type impurities can be injected into the silicon substrate having the load device formed theron.

As described above, the gate electrode conductive pattern to form the transistor is formed in the channel width direction, and then the pocket ion implantation region is formed so that impurities for the pocket ion implantation are not injected into the gate extension even though the gate electrode is misaligned.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity. In addition, when a layer is described as being formed on another layer or on a substrate, the layer may be formed on the other layer or on the substrate, or a third layer may be interposed between the layer and the other layer or the substrate.

FIG. 1 is an equivalent circuit diagram of a CMOS type SRAM cell according to the present invention.

FIG. 2 is an example of the SRAM cell layout illustrating the equivalent circuit diagram of the CMOS type SRAM cell of FIG. 1 realized on a silicon substrate.

FIG. 3 is a graphical representation illustrating current-voltage characteristics of the SRAM cell of FIG. 2 in accordance with the variance of a gate extension of the driver transistor of the SRAM cell.

FIG. 4 is a graphical representation illustrating static noise margin characteristics of the SRAM cell of FIG. 2 in accordance with the variance of a gate extension of the driver transistor of the SRAM cell.

FIGS. 5 and 6 are sectional views illustrating the states that impurities are injected during the pocket ion implantation process for a driver transistor in forming the SRAM cell of FIG. 2.

FIG. 7 is a sectional view illustrating the state that impurities are injected during the pocket ion implantation process for a transfer transistor in forming the SRAM cell of FIG. 2.

FIG. 8 is a graphical representation illustrating current-voltage characteristics after stress is applied on the driver transistor of the SRAM cell of FIG. 2.

FIG. 9 is a graphical representation illustrating degradation rate characteristics after stress is applied on the driver transistor of the SRAM cell of FIG. 2.

FIGS. 10A through 12A and FIGS. 10B and 12B are sectional views and plan views, respectively, illustrating the method of forming the SRAM cell of FIG. 2.

### DETAILED DESCRIPTION OF THE INVENTION

The present invention described herein can be applied to a static random access memory (SRAM) cell using a high load resistor cell or a CMOS type cell, but the present invention will be described in connection with an example of the CMOS type SRAM cell.

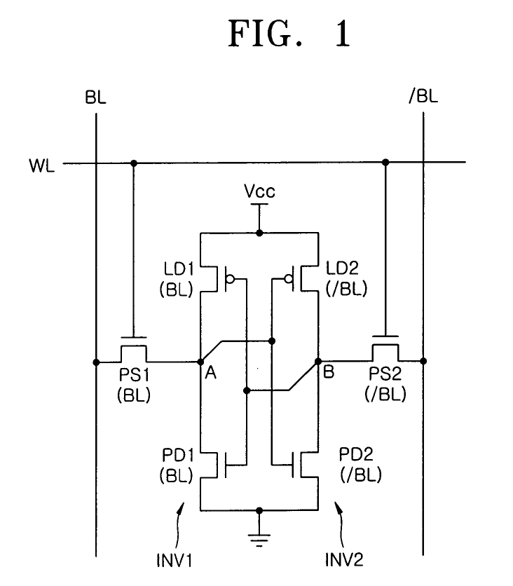

FIG. 1 is an equivalent circuit diagram illustrating one example of the CMOS type SRAM cell according to the present invention.

In particular, the CMOS type SRAM cell is disposed at the cross-section part of a pair of complementary bit lines, that is, a bit line BL and a bit line bar /BL, and a word line WL. The CMOS type SRAM cell is composed of a pair of driver transistors PD1, PD2, a pair of transfer transistors PS1, PS2, and a pair of load transistors LD1, LD2. The pair of driver transistors PD1, PD2, and the pair of transfer transistors PS1, PS2 are composed of NMOS transistors, while the pair of load transistors LD1, LD2 are composed of PMOS transistors.

Among the six transistors of the SRAM cell, the load transistor LD1 and the driver transistor PD1 form a CMOS inverter INV1, and the load transistor LD2 and the driver transistor PD2 form a CMOS inverter INV2. The mutual input-output terminals (nodes A, B) of the one pair of the CMOS inverters are cross-coupled, and form a flip-flop circuit as an information storage for storing one bit of information.

The first driver transistor PD1 and the first transfer transistor PS1 are connected in series. The source region of the first driver transistor PD1 is connected to a reference voltage Vss, and the drain region of the first transfer transistor PS1 is connected to a first bit line BL. In the same way, the second driver transistor PD2 and the second transfer transistor PS2 are connected in series. The source region of the second driver transistor PD2 is connected to a reference voltage Vss, and the drain region of the second transfer transistor PS2 is connected to a second bit line /BL. The first and second bit lines BL, /BL maintain inverse information.

The source region and the drain region of the first load transistor LD1 are connected to the power supply voltage Vcc and the drain region of the first driver transistor PD1, respectively. The source region and the drain region of the second load transistor LD2 are connected to the power supply voltage Vcc and the drain region of the second driver transistor PD2, respectively. The gate electrode of the first driver transistor PD1 and the gate electrode of the first load transistor LD1 are connected to a second node B, and the gate electrode of the second driver transistor PD2 and the gate electrode of the second load transistor LD2 are connected to a first node A. Further, the gate electrodes of the first and second transfer transistors PS1, PS2 are connected to a word line WL.

Describing the operation of the circuit structured as above, when the first node A of the CMOS inverter INV1 is high (H), the second driver transistor PD2 is turned on, so that the second node B of the other CMOS inverter is low (L). Thus, the first driver transistor PD1 is turned off, and then, the first node A is maintained high (H). That is, the state of the first and second nodes is maintained by the latch circuit in which a pair of the inverters INV1, INV2 are cross-coupled, so that information is saved while the power is supplied.

If the word line is high, the transfer transistors PS1, PS2 are turned on, and since the latch circuit and the complementary bit lines BL, /BL are electrically connected, the potential state (H or L) of the nodes A, B is presented in the bit lines BL, /BL, and is read as the information of the SRAM cell. In order to write information in the SRAM cell, the word line is set to high (H), and the transfer transistors PS1, PS2 are turned on so that the information of the bit lines BL, /BL is transferred to the nodes A, B.

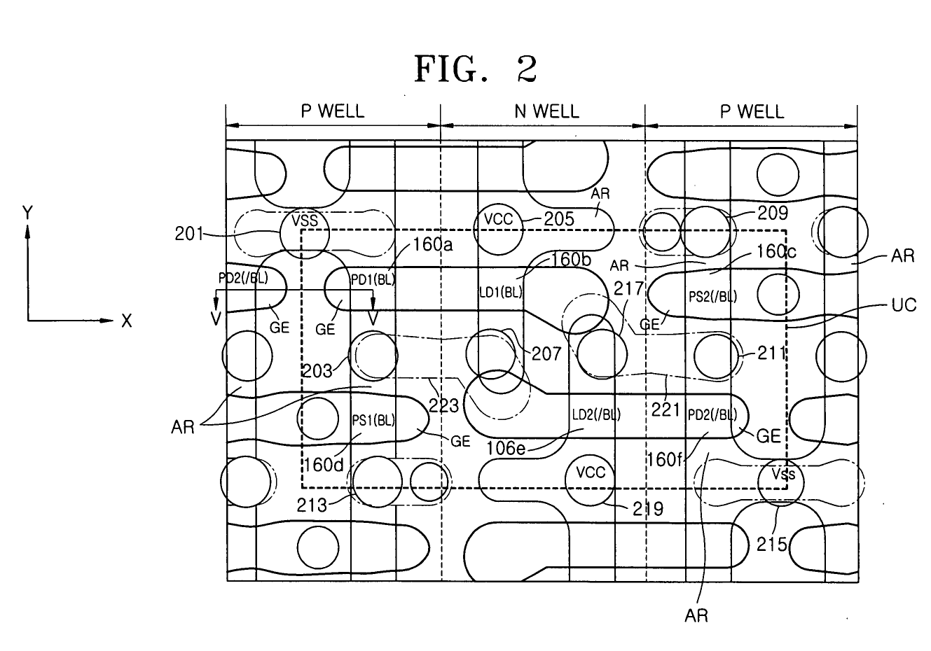

FIG. 2 is an example of the SRAM cell layout illustrating the equivalent circuit diagram of the CMOS type SRAM cell of FIG. 1 realized on a silicon substrate.

In particular, the SRAM cell is structured such that unit cells, each unit cell being referred to as a reference letter “UC”, are repeatedly aligned linearly and symmetrically. Among the transistors of the SRAM cell, the transfer transistors PS1, PS2 and the driver transistors PD1, PD2 are formed in a P-well region, and the load transistors LD1, LD2 are formed in an N-well region.

A gate electrode 160a of the first driver transistor PD1 and a gate electrode 160b of the first load transistor LD1 are disposed in the X-axis direction, that is, the width of the channel. The gate electrode 160a of the first driver transistor PD1 and the gate electrode 160b of the first load transistor LD1 are formed as a first common electrode. The gate electrode 160a of the first driver transistor PD1 includes a gate extension GE. The gate extension GE is protruded or extended in the X-axis direction (−X) on an inactive region separated from an active region AR, which is extended in the Y-axis direction.

A gate electrode 160b of the first load transistor LD1 and a gate electrode 160c of the second transfer transistor PS2, which are spaced in parallel in the X-axis direction, are aligned. The gate electrode 160c of the second transfer transistor PS2 includes a gate extension GE. The gate extension GE is protruded or extended in the X-axis direction (−X) on an inactive region separated from an active region AR, which is extended in the Y-axis direction.

A gate electrode 160d of the first transfer transistor PS1 is disposed along the X-axis direction, being spaced from the first common gate electrode 160a, 160b in the Y-axis direction, that is, channel length, and being spaced from the gate electrode 160c of the second transfer transistor PS2 in the diagonal direction. The gate electrode 160d of the first transfer transistor PS1 includes a gate extension GE. The gate extension GE is protruded or extended in the X-axis direction on an inactive region separated from an active region AR, which is extended in the Y-axis direction.

A gate electrode 160f of the second driver transistor PD2 and a gate electrode 160e of the second load transistor LD2 are disposed along the X-axis direction, being spaced from the first common gate electrode 160a, 160b and the gate electrode 160c of the second transfer transistor PS2 in the Y-axis direction, that is, channel length, and being spaced from the first common gate electrode 160a, 160b of the first driver transistor PD1 and the first load transistor LD1 in the diagonal direction. The gate electrode 160f of the second driver transistor PD2 and the gate electrode 160e of the second load transistor LD2 are formed as a second common electrode. The gate electrode 160f of the second driver transistor PD2 includes a gate extension GE. The gate extension GE is protruded or extended in the X-axis direction on an inactive region separated from an active region AR, which is extended in the Y-axis direction.

A source and a drain (not shown) are disposed in the Y-axis direction up and down from the gate electrode 160a of the first driver transistor PD1, that is, the channel length direction, and a Vss contact 201 and an active contact (drain contact) 203 are formed in the source and the drain. A source and a drain (not shown) are disposed in the Y-axis direction up and down from the gate electrode 160b of the first load transistor LD1, that is, the channel length direction, and a Vcc contact 205 and an active contact (drain contact) 207 are formed in the source and the drain. A source and a drain (not shown) are disposed in the Y-axis direction up and down from the gate electrode 160c of the second driver transistor PS2, that is, the channel length direction, and active contacts 209, 211, that is, a drain contact 209 and a source contact 211, are formed in the source and the drain.

A source and a drain (not shown) are disposed in the Y-axis direction up and down from the gate electrode 160d of the first transfer transistor PS1, that is, the channel length direction, and active contacts 203, 213, that is, a source contact 203 and a drain contact 213, are formed in the source and the drain, respectively. A source and a drain (not shown) are disposed in the Y-axis direction up and down from the gate electrode 160f of the second driver transistor PD2, that is, the channel length direction, and a Vss contact 215 and an active contact (drain contact) 211 are formed in the source and the drain. A source and a drain (not shown) are disposed in the Y-axis direction up and down from the gate electrode 160e of the second load transistor LD2, that is, the channel length direction, and a Vcc contact 219 and an active contact (drain contact) 217 are formed in the source and the drain.

The active contact (drain contact) 211 of the second driver transistor PD2, the active contact (source contact) 211 of the second transfer transistor (PS2), and the active contact (drain contact) 217 of the second load transistor LD2 are connected to the first common electrode 160a, 160b of the first driver transistor PD1 and the first load transistor LD1 through a local interconnection line 221. The active contact (drain contact) 203 of the first driver transistor PD1, the active contact (source contact) 203 of the first transfer transistor (PS1), and the active contact (drain contact) 207 of the first load transistor LD1 are connected to the second common electrode 160e, 160f of the second driver transistor PD2 and the second load transistor LD2 through a local interconnection line 223. In FIG. 2, the portions denoted as circles present contact portions.

However, the SRAM cell of FIG. 2 may cause much threshold voltage mismatch, that is, threshold voltage difference (Δ Vth) between the transistors connected to the two nodes of the bit line BL and the bit line bar /BL, when misalignment occurs in the X-axis direction at the gate electrode during a photolithography process in the case that the transistors are aligned in one line along the X-axis direction.

Particularly, even though the SRAM cell of FIG. 2 does not cause much threshold voltage mismatch between the transfer transistors PS1, PS2 and the load transistors LD1, LD2 connected to the two nodes of the bit line BL and the bit line bar /BL, it causes much threshold voltage mismatch between the driver transistors PD1, PD2 connected to the two nodes of the bit line BL and the bit line bar /BL, thereby reducing a static noise margin and a cell current.

The phenomenon of the threshold voltage mismatch between the transistors connected to the two nodes of the bit line BL and the bit line bar /BL depends on various formation process variables, but particularly, when the length of the gate extension GE of the driver transistors PD1, PD2 during the photolithography process is changed, and the length of the gate extension GE during the pocket ion implantation process for suppressing short channel effect is changed to thereby change the amount of the injected impurities by inclined ion implantation, the threshold voltage mismatch occurs.

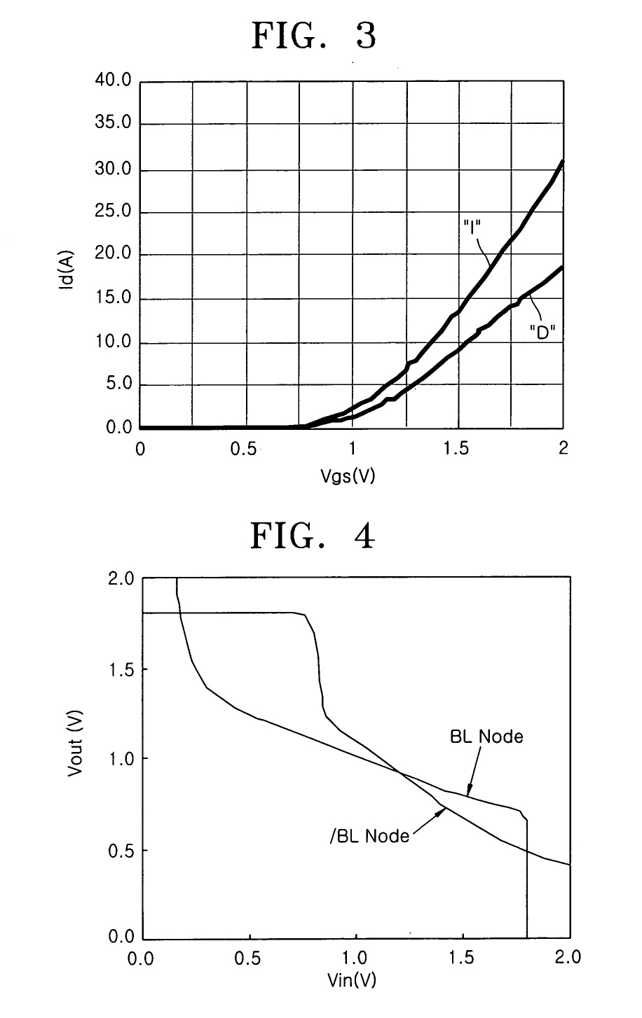

FIG. 3 is a graphical representation illustrating current-voltage characteristics of the SRAM cell of FIG. 2 in accordance with the variance of a gate extension of the driver transistor of the SRAM cell.

In particular, FIG. 3 shows the results measured by applying 2.0 V of voltage between a drain and a source. The X-axis presents a gate voltage Vgs applied to the gate electrode of a driver transistor, and the Y-axis presents a current Id flowing through the drain. As described above, the length of the gate extension of the driver transistor is changed during the photolithography process to form the gate electrode of the SRAM cell, and in accordance with the length of the gate extension, the injection amount of the impurities injected by inclined ion implantation during a subsequent process, pocket ion implantation process are changed. Therefore, in the case that the gate extension of the driver transistor is reduced as designated by a reference letter “D”, it is found that a threshold voltage is reduced and a cell current is reduced in comparison with the case that the gate extension designated by a reference letter “I” is increased.

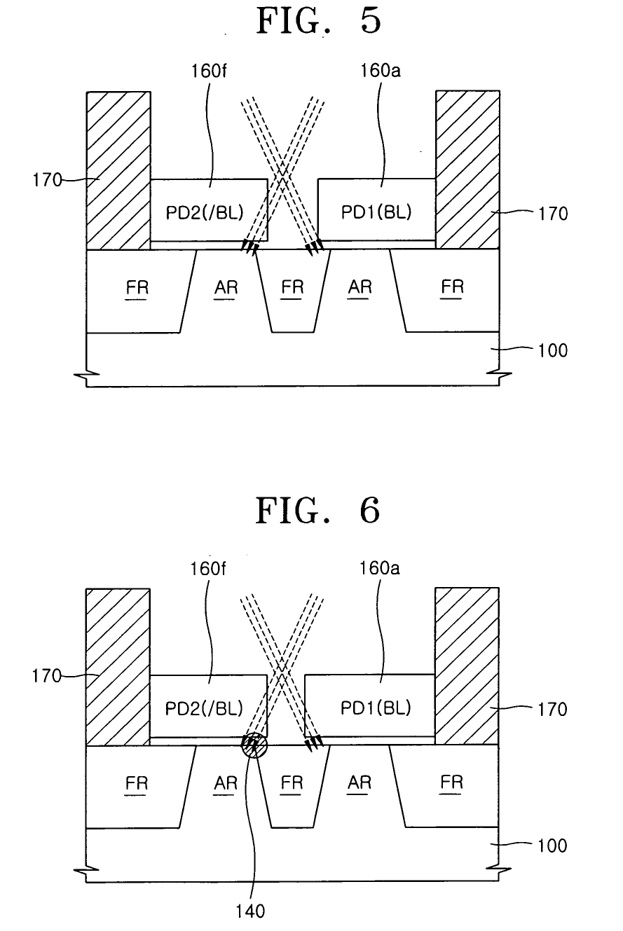

FIG. 4 is a graphical representation illustrating static noise margin characteristics of the SRAM cell of FIG. 2 in accordance with the variance of the gate extension of the driver transistor of the SRAM cell.

In particular, the X-axis presents a voltage Vin applied to a node A in the equivalent circuit of FIG. 1, and the Y-axis presents a voltage Vout output from a node B. In the case that the gate extension of the driver transistor is changed upon the occurrence of misalignment in the SRAM cell, the distance between the bit line and the bit line bar is reduced, thereby degrading the static noise margin characteristics as shown in FIG. 4.

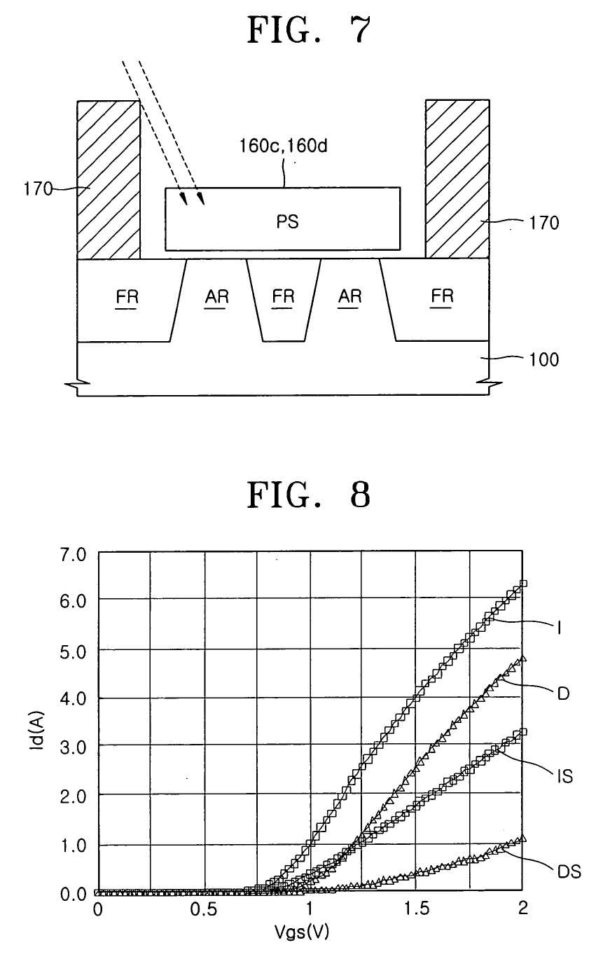

FIGS. 5 and 6 are sectional views illustrating the states that impurities are injected during the pocket ion implantation process of a driver transistor in forming the SRAM cell of FIG. 2.

In particular, FIGS. 5 and 6 illustrate the pocket ion implantation process by using the section taken along a line of V-V of FIG. 2, that is, the section in accordance with a unit cell and its adjacent cell. FIGS. 5 and 6 present the results of the pocket ion implantation process in the cases that the gate electrodes 160a, 160f of the driver transistors PD1, PD2 in the SRAM cell of FIG. 2 are not misaligned and are misaligned, respectively. In FIGS. 5 and 6, “AR” represents an active region, and “FR” represents an inactive region (field region).

The pocket ion implantation process is performed to suppress the short channel effect, and to surround the lower portions of the source/drain (not shown). The pocket ion implantation process is performed by P-type impurities being injected into the silicon substrate 100 having the transfer transistors PS1, PS2 and the driver transistors PD1, PD2 to form an NMOS transistor in the SRAM cell of FIG. 2, and by injecting N-type impurities into the silicon substrate 100 having the load transistors LD1, LD2 to form a PMOS transistor.

Since the pocket ion implantation process affects even peripheral circuit regions as well as the SRAM cell regions, the pocket ion implantation process injects impurities at the four directions, i.e., left and right and back and forth. Further, a photoresist pattern 170 is formed at the region where impurities are not injected. However, in FIGS. 5 and 6, just two directions are presented for convenience.

As shown in FIG. 5, the gate extension GE of the first and second driver transistors PD1, PD2 is not changed in the case that the gate electrodes 160a, 160f of the driver transistors PD1, PD2 are not misaligned on the silicon substrate 100, and thus, impurities are equally injected to the silicon substrate 100 under the gate electrodes 160a, 160f of the first driver transistor PD1 and the second driver transistor PD2 as designated by arrows during the pocket ion implantation process.

However, as shown in FIG. 6, in the case that the gate electrodes 160a, 160f of the driver transistors PD1, PD2 on the silicon substrate 100 are misaligned toward the left, the gate extension GE of the first driver transistor PD1 is increased, and the gate extension GE of the second driver transistor PD2 is reduced. Thus, impurities are injected more into the gate electrode 160f of the second driver transistor PD2 during the pocket ion implantation process, so that a pocket ion implantation region 140 is formed excessively to cause threshold voltage mismatch.

In particular, as shown in FIG. 6, in which the gate extension GE of the second driver transistor PD2 is reduced, and in the case that more impurities are injected during the pocket ion implantation process, the threshold voltage of the second driver transistor PD2 is increased, and a small amount of current flows.

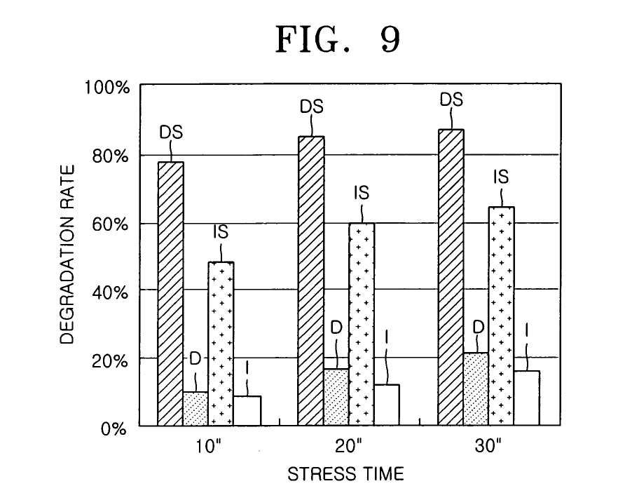

FIG. 7 is a sectional view illustrating the state that impurities are injected during the pocket ion implantation process of the transfer transistor in forming the SRAM cell of FIG. 2.

In particular, as shown in FIG. 7, even though the gate electrode 160d or 160c of the transfer transistor PS in the SRAM cell is misaligned, the impurities injected during the pocket ion implantation process are blocked by the photoresist pattern 170, and are not injected into the silicon substrate 100. Therefore, even though the gate electrode of the transfer transistor PS is misaligned, threshold voltage mismatch does not occur. In FIG. 7, “AR” represents an active region, and “FR” represents an inactive region (field region).

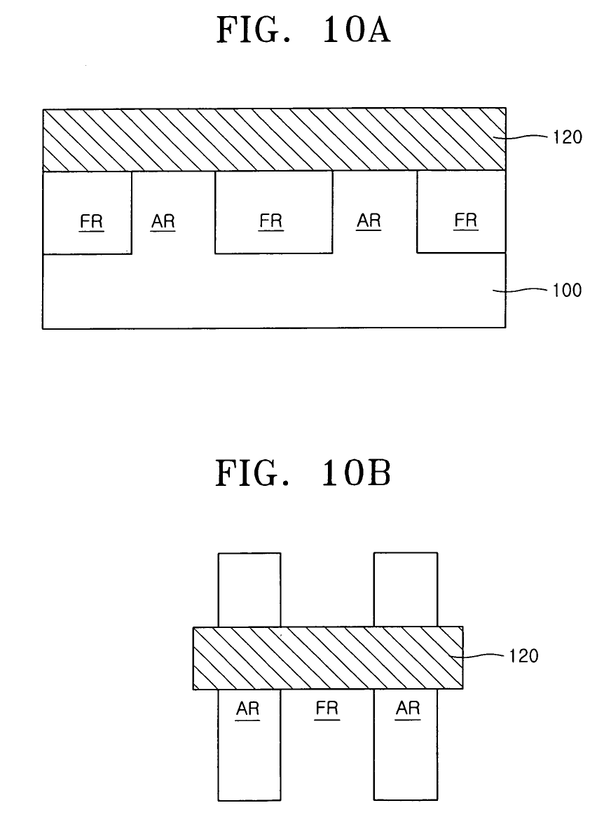

FIG. 8 is a graphical representation illustrating current-voltage characteristics after stress is applied on the driver transistor of the SRAM cell of FIG. 2.

In particular, in the case in which the gate electrode of the driver transistor is misaligned, current-voltage characteristics are measured in accordance with the variance of the gate extension of the driver transistor after stress is applied on the driver transistor.

The graphs designated as reference letters “I” and “D” illustrate the initial current-voltage characteristics in the cases in which the gate extension of the driver transistor is long and short, respectively. The graphs designated as reference letters “IS” and “DS” illustrate the current-voltage characteristics after stress is applied in the cases in which the gate extension of the driver transistor is long and short, respectively. In the cases of the initial current-voltage characteristics and the current-voltage characteristics after stress is applied, voltages of 0.1 V and 4 V are applied between the drain and the source, respectively. The X-axis represents the gate voltage applied to the gate electrode, and the Y-axis represents the current flowing through the drain.

As shown in FIG. 8, it is found that a threshold voltage is significantly reduced after the stress, and the threshold voltage mismatch between the driver transistors connected to the two nodes of the bit line and the bit line bar in the SRAM cell increases, in the case that the gate extension of the driver transistor is short.

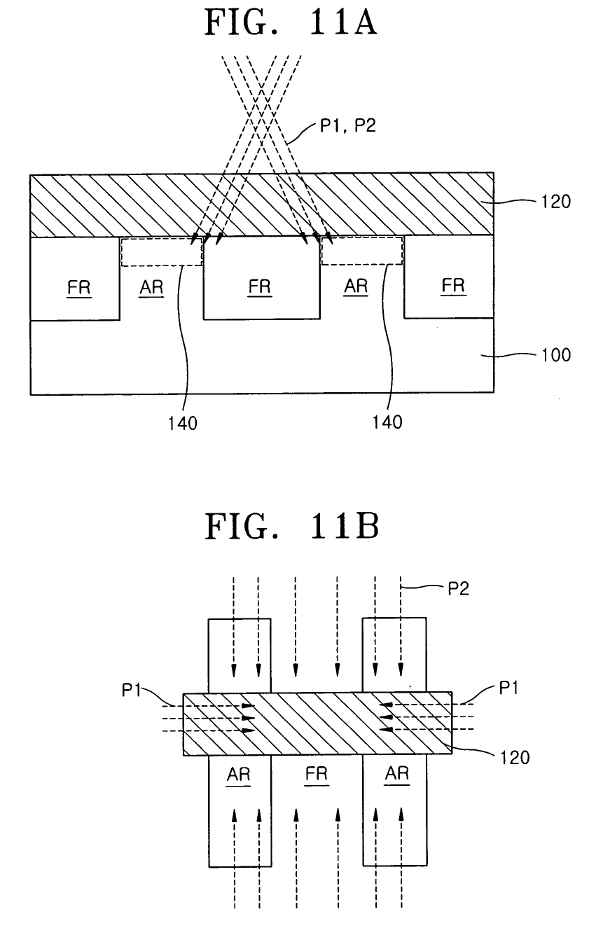

FIG. 9 is a graphical representation illustrating degradation rate characteristics after stress is applied on the driver transistor of the SRAM cell of FIG. 2.

In particular, like numerals of FIG. 9 refer to like elements of FIG. 8. In FIG. 9, the X-axis represents stress time, and the Y-axis represents degradation rate. A voltage of 2 V is applied to the gate electrode. As shown in FIG. 9, in the case that the gate extension of the driver transistor is short, the degradation rate after stress is further increased, so that threshold voltage mismatch between the driver transistors connected to the two nodes of the bit line and the bit line bar in the SRAM cell respectively is further increased.

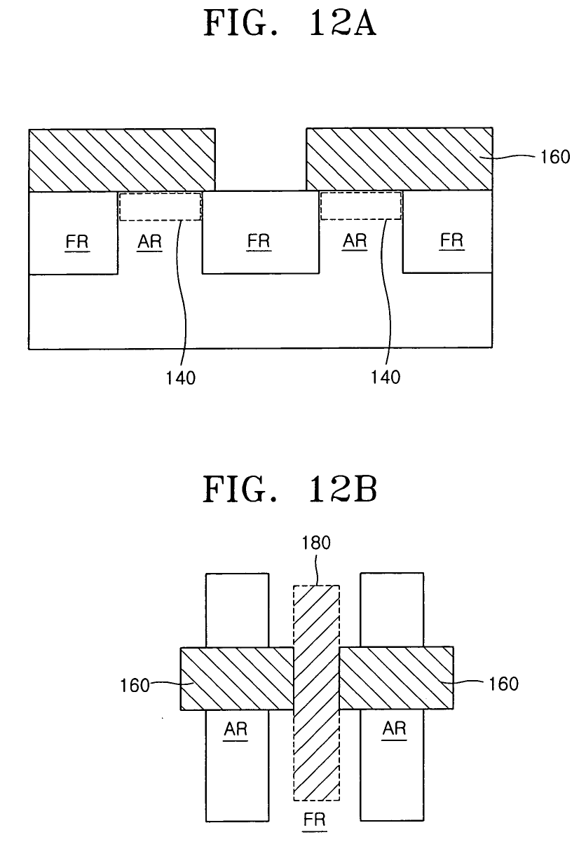

FIGS. 10A through 12A and FIGS. 10B and 12B are sectional views and plan views, respectively, illustrating the method of forming the SRAM cell of FIG. 2.

Referring to FIGS. 10A and 10bB, an active region AR and an inactive region (field region) FR are defined on a silicon substrate 100. A gate electrode conductive pattern 120 of the transistors is formed on the silicon substrate 100 having the active region AR and the inactive region (field region) FR along the X-axis direction of FIG. 2. The conductive pattern 120 may be used for the transfer transistor and the load transistor as well as the driver transistor of the SRAM cell.

Referring to FIGS. 11A and 11B, a pocket ion implantation region 140 is formed by the inclined ion implantation on the silicon substrate 100 having the conductive pattern 120 along the X-axis direction of FIG. 2 (channel width direction) and the channel length direction (Y-axis of FIG. 2). When the pocket ion implantation region 140 is formed, a photoresist pattern 170 is formed in the transistor portions where the pocket ion implantation region 140 is not formed as shown in FIGS. 5 through 7 in order to block the impurities injection, but it is omitted in FIGS. 11A and 11B for clarity.

In particular, when the pocket ion implantation region 140 is formed, impurities are injected at the four directions as shown by the arrows of reference letters P1 and P2 in FIG. 11B, that is, channel width direction and the channel length direction. However, when the pocket ion implantation region 140 is formed, impurities designated by the X-axis direction, that is, direction of P1, are not injected but blocked by the conductive pattern 120.

Therefore, during a subsequent process, when a gate electrode 160 is formed using a photolithography process and the conductive pattern 120, even though misalignment has occurred, impurities for pocket ion implantation are not injected into the gate extension, thereby decreasing threshold voltage mismatch of the transistors connected to two nodes of the bit line and the bit line bar. Further, when the pocket ion implantation region 140 is formed, the height of the photoresist pattern 170 of FIGS. 5 and 6 may be made higher so that impurities are not injected along the X-axis direction, that is, the direction of P1.

Referring to FIGS. 12A and 12B, the conductive pattern 120 is etched using the mask layer 180 along the channel length direction (Y-axis direction), thereby forming the gate electrode 160 of the transistors of the SRAM cell. The gate electrode 160 is used for the transfer transistor and the load transistor as well as the driver transistor of the SRAM cell. Then, the source/drain of the transistors forming the SRAM cell are formed, and a subsequent process is performed.

According to the present invention as described above, after the gate electrode conductive pattern to form transistors is formed in the channel width direction, pocket ions are injected at the four directions, that is, left and right and up and down, by an inclined ion implantation method. Then, patterning is performed on the conductive pattern in the channel length direction, thereby forming a gate electrode of transistors. Accordingly, even though misalignment may have occurred when the gate electrode is formed, impurities for pocket ion implantation are not injected into the gate extension, thereby decreasing the threshold voltage mismatch of the transistors connected to the two nodes of the bit line and the bit line bar.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming an SRAM cell, having two transfer transistors, two driver transistors, and two load devices which are connected with one another in the form of flip-flop, the method comprising:
defining an active region and an inactive region on a silicon substrate;
forming a gate electrode conductive pattern of the transistors on the silicon substrate having the active region and the inactive region formed therein along a channel width direction (X-axis direction);
forming a pocket ion implantation region under the conductive pattern; and
performing a photolithography process on the conductive pattern along a channel length direction (Y-axis direction), thereby forming gate electrodes of the transistors.

2. The method of claim 1, wherein the pocket ion implantation region is formed by injecting impurities in an inclined ion implantation manner into the silicon substrate having the conductive pattern formed thereon along the channel width direction and the channel length direction.

3. The method of claim 1, wherein the transfer transistor and the driver transistor are NMOS transistors, and the load device is a PMOS transistor.

4. The method of claim 3, wherein P-type impurities are injected into the silicon substrate having the transfer transistor and the driver transistor formed thereon to form the pocket ion implantation region, and N-type impurities are injected into the silicon substrate having the load device formed thereon.

5. A method of forming an SRAM cell including a first driver transistor and a first load transistor having a first common gate electrode disposed in an X-axis direction, a second transfer transistor having a gate electrode spaced in parallel from the gate electrode of the first load transistor in an X-axis direction, a first transfer transistor having a gate electrode spaced from the first common gate electrode in a Y-axis direction and disposed in a diagonal direction to the gate electrode of the second transfer transistor, and a second driver transistor and a second load transistor having a second common gate electrode spaced from the second transfer transistor in a Y-axis direction and disposed in a diagonal direction to the first common gate electrode, the method comprising:
defining an active region and an inactive region on a silicon substrate;
forming a gate electrode conductive pattern of the transistors on the silicon substrate having the active region and the inactive region formed therein along a channel width direction (X-axis direction);
forming a pocket ion implantation region under the conductive pattern; and
performing a photolithography process on the conductive pattern along a channel length direction (Y-axis direction), thereby forming gate electrodes of the transistors.

6. The method of claim 5, wherein the pocket ion implantation region is formed by injecting impurities in an inclined ion implantation manner into the silicon substrate having the conductive pattern formed thereon along the channel width direction and the channel length direction.

7. The method of claim 5, wherein the first common gate electrode of the first driver transistor and the second common gate electrode of the second driver transistor include gate extensions extended on an inactive region separated from an active region, which is extended to the Y-axis direction, to a -X and the X-axis directions.

8. The method of claim 7, wherein impurities are not injected into the gate extension along the X-axis direction during the formation of the pocket ion implantation region by the conductive pattern.

9. The method of claim 5, wherein the transfer transistor and the driver transistor are NMOS transistors, and the load device is a PMOS transistor.

10. The method of claim 9, wherein P-type impurities are injected into the silicon substrate having the transfer transistor and the driver transistor formed thereon to form the pocket ion implantation region, and N-type impurities are injected into the silicon substrate having the load device formed thereon.
